(19) United States
(12) Patent Application Publication
(10) Pub. No.: US 2025/0336449 A1
(43) Pub. Date: Oct. 30, 2025

(54) ON-CONTROLLER COMPRESSION OF DATA FROM MULTIPLE READS

(71) Applicant: Micron Technology, Inc., Boise, ID (US)

(72) Inventors: Sivagnanam Parthasarathy, Carlsbad, CA (US); Patrick R. Khayat, San Diego, CA (US); Mustafa N. Kaynak, San Diego, CA (US)

(21) Appl. No.: 19/186,807

(22) Filed: Apr. 23, 2025

Related U.S. Application Data
(60) Provisional application No. 63/638,743, filed on Apr. 25, 2024.

(51) Int. Cl. G11C 16/26; G11C 16/08; G11C 16/30

(52) U.S. Cl. CPC G11C 16/26; G11C 16/08; G11C 16/30; G11C 2207/2254

(57) ABSTRACT

Various embodiments provide for compression on a memory system controller of data generated by multiple reads performed on a set of pages of a memory device of the memory system. Such compression can be useful for storing and subsequently using data (e.g., comprising one-hard-two-soft (1H2S) information data) generated by the multiple reads to perform a management operation on the memory device, such as a read level calibration operation.

### PRIORITY APPLICATION

This application claims the benefit of priority to U.S. Provisional Application Ser. No. 63/638,743, filed Apr. 25, 2024, which is incorporated herein by reference in its entirety.

### TECHNICAL FIELD

Example embodiments of the disclosure relate generally to memory devices and, more specifically, to compression on a memory system controller of data generated by multiple reads performed on a set of pages of a memory device of the memory system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 is a block diagram illustrating an example computing system that includes a memory sub-system, in accordance with some embodiments of the present disclosure.

FIG. 2 is a diagram illustrating an example set of distributions of voltage charge levels and data values stored by a memory cell with respect to hard information and soft information windows, in accordance with various embodiments of the present disclosure.

FIG. 3 is a diagram illustrating multiple page reads performed on a set of distributions of voltage charge levels and data values stored by a memory cell, in accordance with various embodiments of the present disclosure.

FIGS. 4 and 5 illustrate flow diagrams of example methods for compressing, on a memory system controller, data generated by multiple reads performed on a set of pages of a memory device of the memory system, in accordance with some embodiments of the present disclosure.

FIG. 6 is a block diagram of an example computer system in which embodiments of the present disclosure may operate.

### DETAILED DESCRIPTION

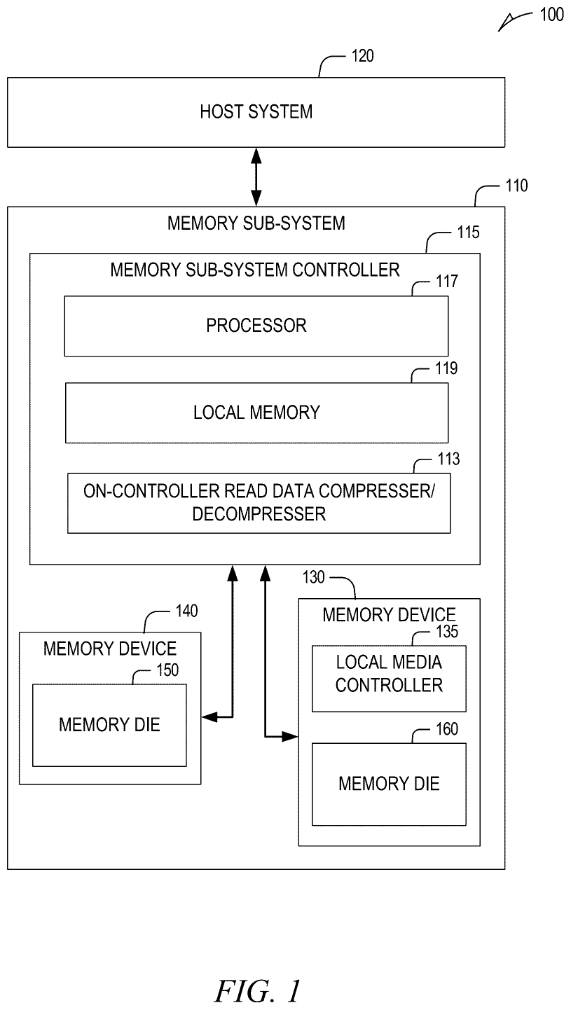

Aspects of the present disclosure are directed to compression on a memory system controller (e.g., memory sub-system controller) of data generated by multiple reads performed on a set of pages of a memory device of the memory system (e.g., memory sub-system). A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can send access requests to the memory sub-system, such as to store data at the memory sub-system and to read data from the memory sub-system.

The host system can send access requests (e.g., write commands, read commands) to the memory sub-system, such as to store data on a memory device at the memory sub-system, read data from the memory device on the memory sub-system, or write/read constructs with respect to a memory device on the memory sub-system. The data to be read or written, as specified by a host request (e.g., data access request or command request), is hereinafter referred to as “host data.” A host request can include logical address information (e.g., logical block address (LBA), namespace) for the host data, which is the location the host system associates with the host data. The logical address information (e.g., LBA, namespace) can be part of metadata for the host data. Metadata can also include error handling data (e.g., error-correcting code (ECC) codeword, parity code), data version (e.g., used to distinguish age of data written), valid bitmap (which LBAs or logical transfer units contain valid data), and so forth.

The memory sub-system can initiate media management operations, such as a write operation on host data that is stored on a memory device or a scan (e.g., media scan) of one or more blocks of a memory device. For example, firmware of the memory sub-system can re-write previously written host data from a location of a memory device to a new location as part of garbage collection management operations. The data that is re-written, for example as initiated by the firmware, is hereinafter referred to as “garbage collection data.”

“User data” hereinafter generally refers to host data and garbage collection data. “System data” hereinafter refers to data that is created and/or maintained by the memory sub-system for performing operations in response to host requests and for media management. Examples of system data include, and are not limited to, system tables (e.g., logical-to-physical memory address mapping table (also referred to herein as an L2P table), data from logging, scratch pad data, and so forth).

A memory device can be a non-volatile memory device. A non-volatile memory device is a package of one or more die. Each die can comprise one or more planes. For some types of non-volatile memory devices (e.g., NOT-AND (NAND)-type devices), each plane comprises a set of physical blocks. For some memory devices, blocks are the smallest area that can be erased. Each block comprises a set of pages. Each page comprises a set of memory cells, which store bits of data. The memory devices can be raw memory devices (e.g., NAND), which are managed externally, for example, by an external controller. The memory devices can be managed memory devices (e.g., managed NAND), which are raw memory devices combined with a local embedded controller for memory management within the same memory device package.

Generally, writing data to such memory devices involves programming (by way of a program operation) the memory devices at the page level of a block, and erasing data from such memory devices involves erasing the memory devices at the block level (e.g., page level erasure of data is not possible). Certain memory devices, such as NAND-type memory devices, comprise one or more blocks, (e.g., multiple blocks) with each of those blocks comprising multiple pages, where each page comprises a subset of memory cells of the block, and where a single wordline of a block (which connects a group of memory cells of the block together) defines one or more pages of a block (depending on the type of memory cell). Depending on the embodiment, different blocks can comprise different types of memory cells. For instance, a block (a single-level cell (SLC) block) can comprise multiple SLCs, a block (a multi-level cell (MLC) block) can comprise multiple MLCs, a block (a triple-level cell (TLC) block) can comprise multiple TLCs, a block (a quad-level cell (QLC) block) can comprise QLCs, and a block (a penta-level cell (PLC) block) can comprise PLCs. Other blocks comprising other types of memory cells (e.g., higher-level memory cells, having higher bit storage-per-cell) are also possible.

Each memory cell usually comprises a floating-gate transistor, where the level of an electrical charge “trapped” in the floating gate of the floating-gate transistor (of an individual memory cell) can represent one or more bits stored by the individual memory cell. When a charge is applied to the floating gate of the floating-gate transistor (of a memory cell), the charge remains “trapped” there due to the insulating properties of the surrounding materials, and this “trapped” charge alters the threshold voltage of the floating-gate transistor, which changes its conductive state. The threshold voltage determined for the floating-gate transistor translates to one or more bits of data stored on the memory cell and, as such, reading data from a memory cell can involve detecting the current threshold voltage of the memory cell.

Detecting the threshold voltage of memory cells of a wordline (e.g., corresponding to one or more pages) of a NAND-based memory device can involve performing a read strobe on the wordline. A read strobe can comprise applying a read voltage level to a chosen wordline and sensing a response from applying the read voltage level, thereby obtaining sensed data that can be used to identify memory cells (of the chosen wordline) that have their respective threshold voltages below or above the applied read level. Performing a read operation on a NAND-based memory device to read data from one or more given memory cells of a chosen wordline can comprise performing (e.g., applying) one or more read strobes on the chosen wordline.

Each worldline (of a block) can define one or more pages depending on the type of memory cells (of the block) connected to the wordline. For example, for an SLC block, a single wordline can define a single page. For an MLC block, a single wordline can define two pages—a lower page (LP) and an upper page (UP). For a TLC block, a single wordline can define three pages—a lower page (LP), an upper page (UP), and an extra page (XP). For a QLC block, a single wordline can define four pages—a lower page (LP), an upper page (UP), an extra page (XP), and a top page (TP) page. As used herein, a page of LP page type can be referred to as a “LP page,” a page of UP page type can be referred to as a “UP page,” a page of XP page type can be referred to as a “XP page,” and a page of TP page type can be referred to as a “TP page.” Each page type can represent a different level of a cell (e.g., QLC can have a first level for LPs, a second level for UPs, a third level for XPs, and a fourth level for TPs). To write data to a given page, a wordline associated with the given page is programmed according to a page programming algorithm (e.g., that causes one or more voltage pulses or pulses to memory cells of a block based on the memory). Generally, programming a single wordline of a block results all the pages in the single wordline being programmed, where the number pages being programmed depends on the type of block. For example, programming a single wordline of a QLC block usually results in four pages (e.g., LP, UP, XP, TP pages) associated with the single wordline being programmed.

In conventional memory systems (e.g., memory sub-systems), each page of a block (of a memory device) comprises a certain number of codewords, where each codeword comprises a payload portion (or payload) for storing a certain number of data sectors (or sectors) that store data (or host data) from a host system, and where each codeword comprises a non-payload portion that can include protection data (e.g., parity data, such as low-density parity-check (LDPC) data) for protecting (e.g., facilitating error correction) of all the data in the codeword. The non-payload portion can also include protection information, cyclic redundancy check (CRC) data, and metadata (e.g., security metadata and firmware metadata), and the like. For instance, the size of a sector used by a host system can be set to 512 bytes, and NAND-type memory devices can be configured with 16-kilobyte pages each comprising four 4096-byte codewords, and with each codeword comprising a payload that stores eight 512-byte sectors and comprising parity data for facilitating error correction of the host data stored in the payload. Depending on the memory cell type, a reading of a wordline can comprise one or more pages (e.g., 16-kilobyte pages) being read at a given time. For instance, reading a wordline of a SLC block can result in the reading of one 16-kilobyte page, reading a wordline of a MLC block can result in the reading of two 16-kilobyte pages (UP and LP), reading a wordline of a TLC block can result in the reading of three 16-kilobyte pages (UP, LP, XP), and reading a wordline of a QLC block can result in the reading of four 16-kilobyte pages (UP, LP, XP, and TP). A given block (e.g., SLC, MLC, TLC, QLC block) can comprise multiple wordlines.

Operation of a NAND memory device is not without its challenges, as it is susceptible to various noise, error, and disturbance mechanisms that can compromise data integrity. These disturbances include, but are not limited to, retention issues, cell-to-cell coupling, read disturb, and cross-temperature. To ensure the reliability and longevity of the NAND memory device, these disturbances must be managed effectively. Typically, such management is executed in the background, allowing the system to maintain optimal performance without interrupting host data traffic. Advanced management operations (or features) have been developed to mitigate the effects of these disturbances, often involving multiple reads of an individual page at different read levels (e.g., different read-level voltages), with a certain (e.g., predetermined) voltage difference between each read.

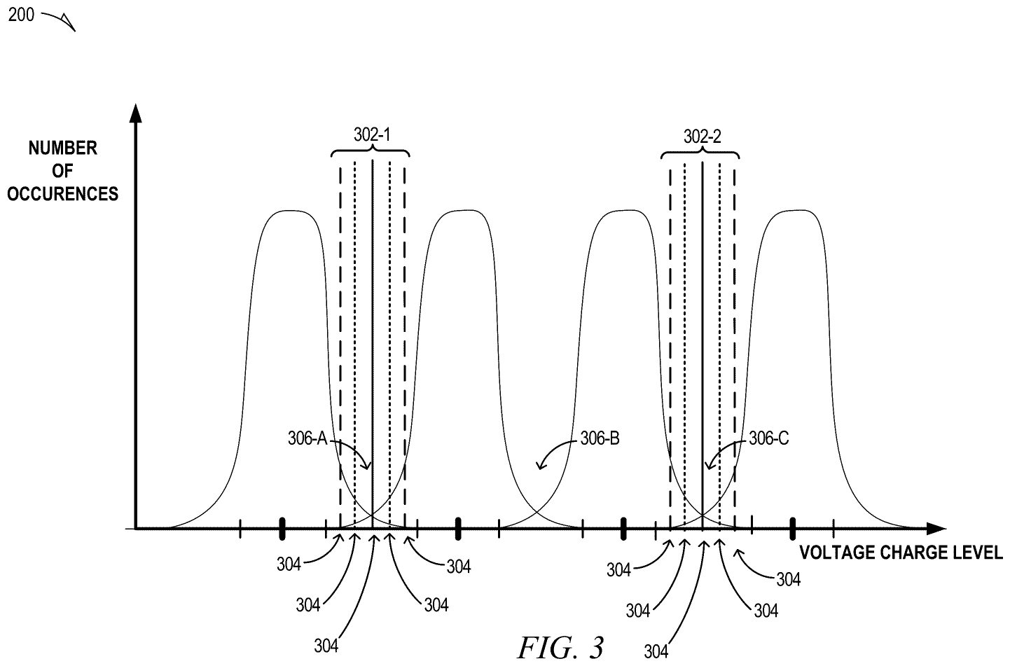

For instance, for multi-level cell (MLC) NAND flash memory, where two bits are stored per memory cell, the voltage distribution of memory cells includes several valleys, each corresponding to different data states of an MLC that makes up the upper page (UP) and the lower page (LP) of an MLC block. To accurately determine the state of a memory cell, multiple reads may be performed around these valleys, within a read window, with a predetermined voltage difference between each read. An example of multiple page reads performed on a MLC of a memory device within a small read window around a valley of a voltage distribution is illustrated and described with respect to FIG. 3 herein.

The multiple reads of an individual page at different read levels can provide visibility into a specific voltage region surrounding the valley, which can be useful for accurate data interpretation (e.g., maintaining the precision of data storage and retrieval) and calibrating the system read levels. Each read can result in generation of hard information data for memory cells of an individual page, generation of soft information (or soft bits) for the memory cells of the individual page, or both, where the hard information data can represent a data value actually stored by the memory cells of the individual page, and where the soft information data can represent the reliability, confidence level, or probability of the hard information data.

One of the challenges in deploying management operations (or features) is the memory requirement on a memory system controller's (e.g., memory sub-system controller) operational memory or buffer. Certain management operations, such as system read level calibration, that cause multiple page reads in a small voltage window, also cause information (e.g., hard and soft information data) generated by the multiple reads to be stored (e.g., held) in a memory system controller's memory for subsequent use (e.g., use by the management operation to accomplish its respective task/goal). Unfortunately, this stored information data (from multiple page reads) represents multiple pages worth of read data for each page read and occupies useful memory space on the memory system controller (e.g., memory space that could be used by the memory system controller for other operations). Additionally, as the demand for higher storage capacities and faster data access continues to grow with respect to memory devices, so does the need for efficient memory management on a memory system controller.

Various embodiments presented herein can cure these and other deficiencies of conventional memory systems by compression on a memory system controller (e.g., memory sub-system controller) of data generated by multiple reads performed on a set of pages of a memory device of the memory system (e.g., memory sub-system). For instance, an embodiment described herein can enhance data management in a memory system (e.g., comprising a NAND-type memory device) when performing with multiple page reads of a memory device within a small read window (e.g., small voltage read window). Such multiple page reads can be performed by, and useful for, a management operation of the memory system, such as a read level calibration operation (e.g., coarse threshold estimation or syndrome weight-based approach to read level calibration). Such multiple page reads can also be useful for other soft read mode operations performed on the memory system. Various embodiments described herein can leverage the fact that when multiple page reads are performed in a small read window (e.g., around a specific voltage region, such as a valley within the threshold voltage distribution of a memory cell), the majority of the bits yield the same value across these reads due to the small population of bits whose read values actually change within the read window compared to the overall page size. For some embodiments, the smaller the read window (e.g., voltage window), the higher the compression ratio possible.

According to various embodiments, a memory system: causes multiple page read on a set of pages of a memory device, which results in read data being stored in a set of page buffers of the memory device; and compresses the read data as it is read from the set of page buffers into a memory (e.g., on-controller buffer) of a memory system controller (e.g., memory sub-system controller), which then stores the compressed data. The read data read from the set of page buffers can comprise hard information data, soft information data, or both (e.g., 1H2S information data) generated by the multiple page reads. The compression of the read data as it is read from the set of page buffers enables some embodiments to significantly reduce the amount of data that needs to be managed and stored by the memory system controller. Subsequently, when the memory system controller needs to access the original (e.g., the system or firmware of the memory system requires access to the original data), uncompressed read data, the compressed read data can be read from the memory of the memory system controller and can be decompressed as it is read from the memory of the memory system controller. Additionally, should the read data need to be stored back in the memory of the memory system controller, it is compressed once again before storage.

The use of various embodiments can address the challenge of memory requirements (e.g., buffer memory requirements) on a memory system controller when it comes to storing read data from multiple page reads, such as during a read level calibration operation. Additionally, the use of various embodiments can enable efficient handling of multiple page reads without the need for additional memory on the memory system controller, thereby enhancing the overall performance of the memory system without increasing the physical size, cost, or power consumption of the memory system controller.

As used herein, a translation unit (TU) of a memory device can comprise (e.g., store) one or more codewords, and can be referenced by a physical memory address (or physical address) of the memory device. For various embodiments, a logical memory address (or logical address) of a memory system is translated into a physical memory address of a memory device.

As used herein, hard information data (or hard bits) can comprise one or more bits determined based on detecting a voltage charge currently stored (e.g., or held) by a memory cell (of a block of a memory device) and based on one or more hard voltage thresholds (or hard thresholds) associated with the memory cell. For various embodiments, hard information data determined for a memory cell represents a data value actually stored by the memory cell. A hard voltage threshold (or hard threshold) of a memory cell can refer to a discrete voltage threshold level (or discrete threshold level) that separates different ranges (or windows) of voltage charge that the memory cell can store and the different data values represented by each of those different ranges (or windows). For instance, a memory cell of a QLC block can store 4-bits, and can have 16 windows for values (e.g., binary values of 0000 to 1111) separated by 15 discrete threshold levels. Hard voltage thresholds are generally located within (e.g., in the center of) voltage distribution valleys associated with a memory cell.

As used herein, soft information data (or soft bits) of a memory cell can comprise one or more bits that indicate where the voltage charge (detected as being stored by a memory cell) lies between two hard thresholds of the memory cell, thereby providing higher-resolution information regarding the voltage charge currently stored by the memory cell (than provided by hard information data alone). Specifically, soft information data can indicate how close a voltage charge sampled/detected from a memory cell is to a hard threshold of the memory cell and, therefore, indicate the probability that the voltage charge (sampled/detected from the memory cell) was sampled/detected correctly. In this way, soft information data can represent the reliability, confidence level, or probability of the hard information data (hard bits) read from one or more memory cells of a memory device, where such the reliability/confidence level/probability can be useful in data error correction techniques. Soft information data can be determined based on detecting a fractional component of a voltage charge currently stored by the memory cell and based on fractional voltage thresholds (e.g., soft thresholds). For instance, where a sampled/detected voltage charge of a memory cell of a TLC block falls between a first voltage threshold and a second voltage threshold, and the hard bits are determined to comprise “101,” the soft bit information (e.g., bit value of “1” or “0”) can indicate whether the sampled/detected voltage charge is closer to the first voltage threshold or the second voltage threshold and the probability of an error in the sampling/detection of the voltage charge. Where hard information data accompanied by soft information data that indicates a voltage charge sampled/detected from a memory cell is close to a hard threshold of the memory cell, that voltage charge has a lower probability of being correct than a voltage charge sampled/detected with soft information that indicates the voltage charge sampled/detected is centered between two hard thresholds. Decode processes (e.g., signal processing algorithms), such as a Low Density Parity Codes (LDPC) process, can use hard information data for a memory cell and soft information data for the memory cell (e.g., in terms of error probabilities) to determine (e.g., decode) a data value stored by the memory cell.

An example of hard information data and soft information obtained for one or more memory cells (e.g., a given page or a given codeword) of a memory device can include, without limitation, one hard bit-two soft bit (1H2S) information for each of the memory cells.

As used herein, a read window, which may be referred to as a read window width, can refer to a distance (e.g., in voltage) between adjacent threshold voltage (Vt) distributions. A read window may also be referred to as a “valley margin” since the Vt distributions include respective peaks, with the regions between being referred to as valleys.

Disclosed herein are some examples of compression on a memory system controller of data generated by multiple reads performed on a set of pages of a memory device of the memory system, as described herein.

FIG. 1 illustrates an example computing system 100 that includes a memory sub-system 110, in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random-access memory (DRAM) and synchronous dynamic random-access memory (SDRAM).

Some examples of non-volatile memory devices (e.g., memory device 130) include a NAND type flash memory and write-in-place memory, such as a three-dimensional (3D) cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130 can include one or more arrays of memory cells. One type of memory cell, for example, SLCs, can store one bit per cell. Other types of memory cells, such as MLCs, TLCs, QLCs, and penta-level cells (PLCs), can store multiple or fractional bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks. As used herein, a block comprising SLCs can be referred to as a SLC block, a block comprising MLCs can be referred to as an MLC block, a block comprising TLCs can be referred to as a TLC block, and a block comprising QLCs can be referred to as a QLC block.

Although non-volatile memory components such as NAND type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or another suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands, requests, or operations from the host system 120 and can convert the commands, requests, or operations into instructions or appropriate commands to achieve the desired access to the memory devices 130 and/or the memory device 140. The memory sub-system controller 115 can be responsible for other operations such as wear leveling operations, garbage collection operations, error detection and ECC operations, encryption operations, caching operations, and address translations between a logical address (e.g., LBA, namespace) and a physical memory address (e.g., physical block address) that are associated with the memory devices 130. The memory sub-system controller 115 can further include host interface circuitry to communicate with the host system 120 via the physical host interface. The host interface circuitry can convert the commands received from the host system 120 into command instructions to access the memory devices 130 and/or the memory device 140 as well as convert responses associated with the memory devices 130 and/or the memory device 140 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local media controller 135) for media management within the same memory device package. An example of a managed memory device is a managed NAND (MNAND) device.

Each of the memory devices 130, 140 include a memory die 150, 160. For some embodiments, each of the memory devices 130, 140 represents a memory device that comprises a printed circuit board, upon which its respective memory die 150, 160 is solder mounted.

The memory sub-system controller 115 includes an on-controller read data compressor/decompressor 113 that enables or facilitates the memory sub-system controller 115 to compress/decompress, on the memory sub-system 115, data generated by multiple reads performed on a set of pages of a memory device (e.g., 130, 140). For instance, the on-controller read data compressor/decompressor 113 can cause the processor 117 of the memory sub-system controller 115 to: cause multiple page reads to be performed on a set of pages of a memory device (e.g., 130, 140); receive read data (e.g., comprising hard information data, soft information data, or both) from a set of page buffers of a memory device (e.g., 130, 140); compress the read data to compressed read data; store the compressed read data to a buffer of the memory sub-system controller 115 (e.g., buffer corresponding to storage space allocated on the local memory 119); read the compressed read data from the buffer; and decompress the compressed read data to generate a copy of the (original) read data for use by the memory sub-system controller 115.

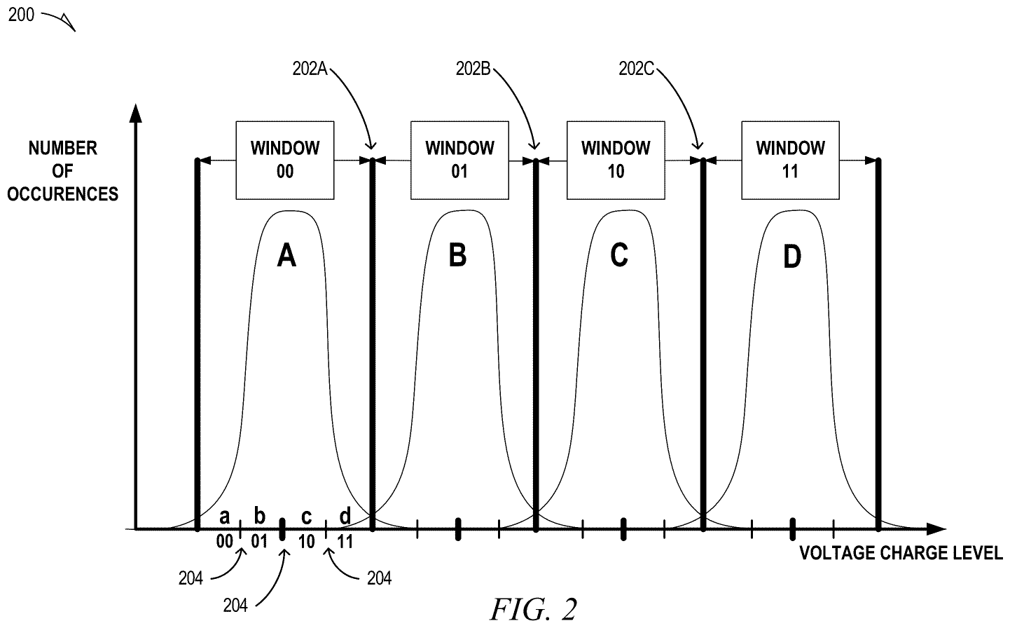

FIG. 2 is a diagram illustrating an example set of distributions 200 of voltage charges and data values stored by a memory cell with respect to windows for hard information and soft information, in accordance with various embodiments of the present disclosure. Referring now to FIG. 2, a 2-bit per cell memory device (e.g., a MLC memory device) is illustrated as comprising a total of 4 voltage charge ranges, areas or windows of information A-D divided by three threshold levels which are designated as 202A, 202B and 202C. These windows can correspond to read windows within which voltage is oversampled to generate soft information data. By way of example, a 4-bit per cell device has 16 windows for values to be written with 15 threshold levels separating these values. As described herein, the discrete voltage thresholds separating the information values can be referred to as hard voltage thresholds. Data detection using hard voltage thresholds can be referred to as slicer detection. Data (e.g., bits) represented by hard voltage thresholds can be referred to herein as hard information data (e.g., hard bits). Soft information data (e.g., soft bits) can indicate where a value lies between the hard voltage thresholds and can be referred. Soft information data relates to how close a particular sample is to a hard threshold and therefore to the probability that the voltage sampled was sample/detected correctly. In FIG. 2, each hard information window 00-11 is over sampled with an additional 2 bits of soft information data. The voltage range of each hard information window is divided into four sub-ranges that are designated as a-d for hard window 00. The sub-ranges are separated within each hard window by three soft voltage thresholds 204, a number of which are specifically designated. A total of 16 soft window areas, or 4 bits, are therefore used to describe 2 bits of user data. The number of soft information bits can be extended indefinitely. For instance, a memory cell storing 4-bits of data can be oversampled by 3 additional soft information bits, and can require 7 bits (4 hard information bits and 3 soft information bits) of data to fully describe the 4 bits of data stored by a memory cell. Each hard information window can correspond to a voltage range of the memory cell, and each soft information window can correspond to a voltage sub-range within one of the hard information windows.

FIG. 3 is a diagram illustrating multiple page reads performed on the set of distributions 200 of FIG. 2, in accordance with various embodiments of the present disclosure. In particular, the set of distributions 200 can represent threshold voltage (vt) distributions for an MLC that stores 2 bits per cell, where 306-A, 306-B, and 306-C, respectively, represent the 1^{st}, 2^{nd}, and 3^{rd} valleys of the MLC. The first valley (306-A) and third valley (306-C) can correspond to the upper page (UP) of the MLC, and the second valley (306-B) can correspond to the lower page (LP) of the MLC. In FIG. 3, multiple reads (304) are performed at read window 302-1 and at read window 302-2 with respect to the upper page (UP). In particular, there are five different upper page reads illustrated in each of the read windows 302-1, 302-2. There is a predetermined delta voltage difference (e.g., 40 mV) between each of the page reads, and each read window 302-1, 302-2 has a predetermined voltage size (e.g., 160 mV). Depending on the embodiment, the delta voltage difference between page reads, the size of the read window, or both can be the same or different between different read windows 302-1, 302-2 (e.g., one or both can change between different valleys). Overall, the multiple page reads of the read window 302-1 can provide visibility of a certain voltage region around the first valley (306-A) with respect to the upper page of the MLC, and the multiple page reads of the read window 302-2 can provide visibility of a certain voltage region around the third valley (306-B) with respect to the upper page of the MLC. If the MLC has a voltage charge that falls between the two valleys 306-A and 306-C, the upper page of the MLC has a value of 0 (e.g., UP=0), and if the MLC has a voltage charge that falls to the left of the first valley 306-A or to the right of the third valley 306-C, the upper page of the MLC has a value of 1 (e.g., UP=1).

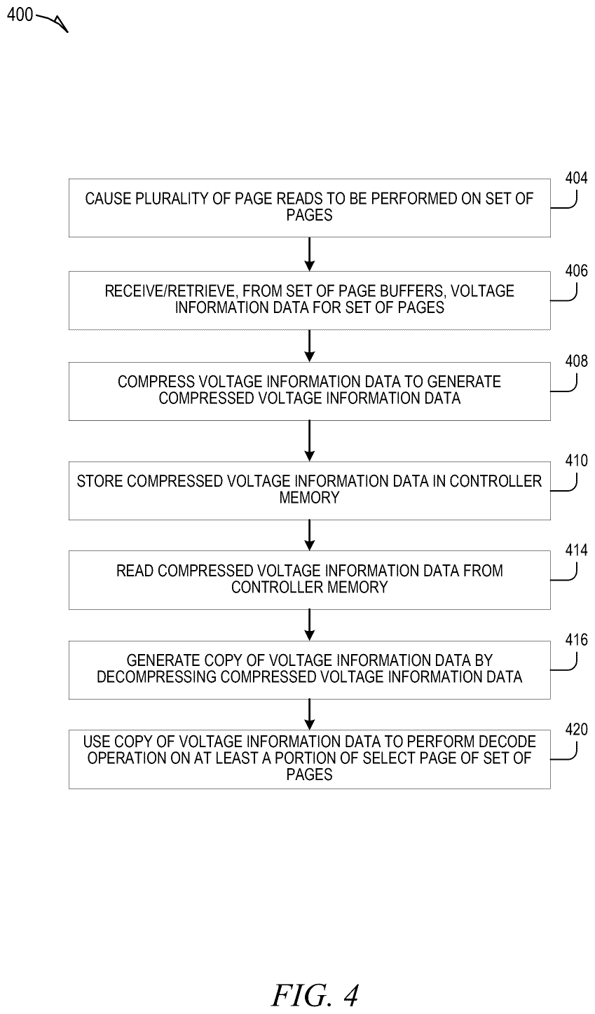

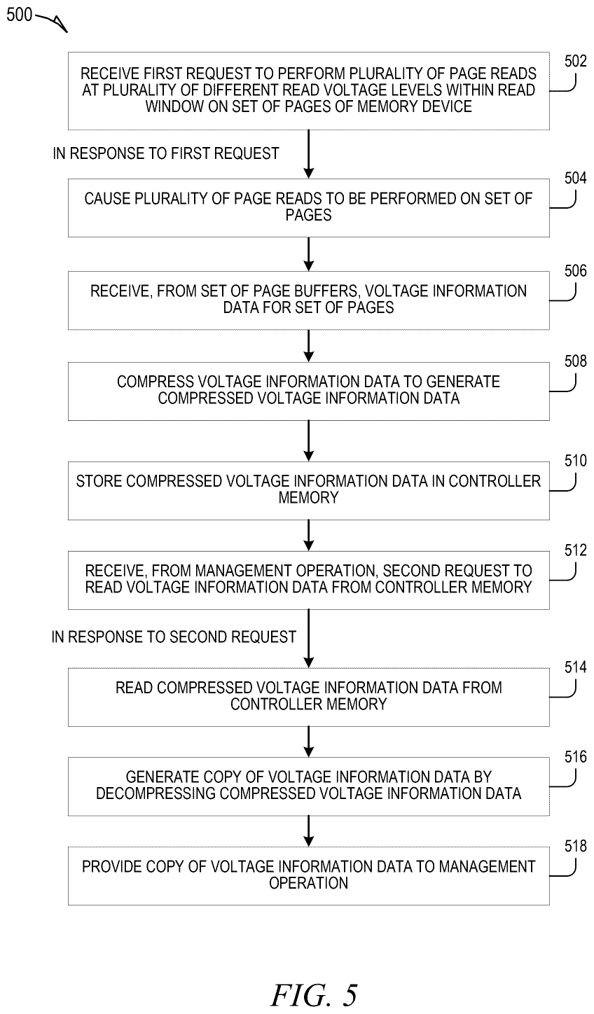

FIGS. 4 and 5 illustrate flow diagrams of example methods 400, 500 for compressing, on a memory system controller, data generated by multiple reads performed on a set of pages of a memory device of the memory system, in accordance with some embodiments of the present disclosure. Any of methods 400, 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, one or more of methods 400, 500 is performed by the memory sub-system controller 115 of FIG. 1 based on the on-controller read data compressor/decompressor 113. Additionally, or alternatively, for some embodiments, one or more of methods 400, 500 is performed, at least in part, by the local media controller 135 of the memory device 130 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are used in every embodiment. Other process flows are possible.

Referring now to method 400 of FIG. 4, at operation 404, a processing device of a memory system controller (e.g., the processor 117 of the memory sub-system controller 115) causes a plurality of page reads to be performed on a set of pages of a memory device (e.g., 130 or 140) at a plurality of different read voltage levels within a read window. Each page read can comprise applying a read strobe at a select read voltage level on a wordline associated with a select page of the set of pages. For some embodiments, the plurality of page reads generates voltage information data in a set of page buffers (e.g., a set of latches) of the memory device. The size of the read window, position of the read window, or both can be determined based on the intended use of the voltage information data. For example, the read window can be a small read window, and can be centered relative to a hard threshold or relative to a valley of a voltage distribution of a memory cell (where the position and number of valleys can vary between different memory cell types) to provide visibility into a specific voltage region surrounding the valley. As noted herein, the smaller the read window, the higher the compression ratio that can be achieved by the processing device. According to one example, the read window can have a size of 160 mV. The number of page reads performed, and the voltage difference between read voltage levels of the plurality of different read voltage levels, can be determined based on the size of the read window, the intended use of the voltage information data, or both. For some embodiments, read voltage levels of the plurality of different read voltage levels are based on a predetermined voltage difference. For example, the plurality of page reads can comprise five page reads (e.g., with a read window of 160 mV) having a predetermined voltage difference of 40 mV between the page reads.

At operation 406, the processing device of the memory system controller (e.g., the processor 117) receives (or retrieves), from the set of page buffers, the voltage information data for the set of pages. For various embodiments, the voltage information data describes voltage charges of (e.g., stored by) memory cells of the set of pages. Depending on the embodiment, the voltage information data can comprise soft information data for the set of pages, hard information data (e.g., undecoded hard information data) for the set of pages, or both. For example, the voltage information data can comprise one-hard-one-soft (1H1S) information data for the set of pages, or one-hard-two-soft (1H2S) information data for the set of pages.

For operation 408, the processing device of the memory system controller (e.g., the processor 117) compresses the voltage information data to generate compressed voltage information data. The compression during operation 408 can occur (e.g., in-line) as the voltage information data is received (or retrieved) by the processing device from the set of page buffers.

Subsequently, at operation 410, the processing device of the memory system stores the compressed voltage information data in a controller memory of the memory system controller. The controller memory can be a portion of local memory of the memory system controller (e.g., local memory 119) allocated or reserved to be used as a read data buffer. Alternatively, the controller memory can comprise a separate memory or buffer, which can reserved for use of storing read data received (e.g., retrieved) from page buffers of memory devices.

Thereafter, at operation 414, the processing device of the memory system controller (e.g., the processor 117) reads the compressed voltage information data from the controller memory. For instance, operation 414 can be performed in response to the processing device wanting to access and use a copy of the voltage information data (e.g., use for a management operation on the memory device 130 or 140, such as a read level calibration operation). At operation 416, the processing device of the memory system controller generates a copy of the voltage information data by decompressing (e.g., expanding) the compressed voltage information data. The decompression during operation 416 can occur (e.g., in-line) as the compressed voltage information data is read by the processing device from the controller memory. Alternatively, the compressed voltage information data can be stored in a first portion of the controller memory, the compressed voltage information data can be decompressed (as the copy of the voltage information data) to a second portion of the controller memory, and the processing device can read (e.g., retrieve) the copy of the voltage information data from the second portion. Additionally, for some embodiments, the compressed voltage information data can be removed (e.g., deleted) from the controller memory after the copy of the voltage information data is generated and received (e.g., retrieved) or used by the processing device.

Subsequently, the processing device of the memory system controller can use the copy of the voltage information data to perform an operation. For instance, at operation 420, the processing device of the memory system controller can use the copy of the voltage information data to perform a decode operation (e.g., by a decoder of the memory system controller, such as a LDPC decoder) on at least a portion (e.g., codeword) of a select page of the set of pages.

Referring now to FIG. 5, at operation 502, the processing device of the memory system controller (e.g., the processor 117) receives, from a management operation (e.g., being performing by the memory system controller), a first request to perform a plurality of page reads on a set of pages of the memory device at a plurality of different read voltage levels within a read window. In response to the first request, method 500 proceeds to operation 504. According to various embodiments, operations 504, 506, 508, 510 are respectively similar to operations 404, 406, 408, 410 described with respect to FIG. 4.

Eventually, at operation 512, the processing device of the memory system controller (e.g., the processor 117) receives, from the management operation, a second request to read the voltage information data from the controller memory. In response to the second request, method 500 proceeds to operation 514. According to various embodiments, operations 514, 516 are respectively similar to operations 414, 416 described with respect to FIG. 4. Subsequently, at operation 518, the processing device provides the copy of the voltage information data to the management operation, which can perform one or more additional operations using at least some portion of the voltage information data.

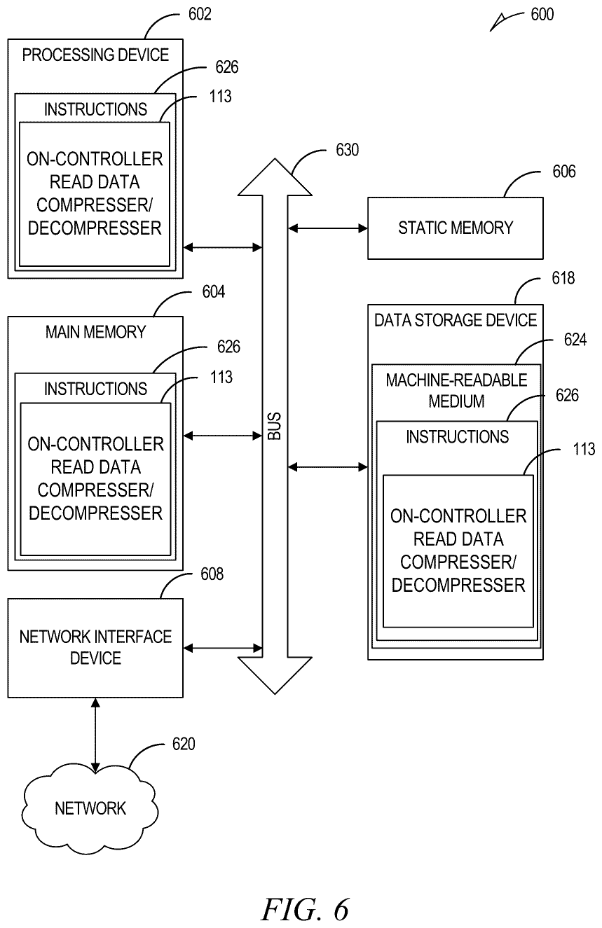

FIG. 6 illustrates an example machine in the form of a computer system 600 within which a set of instructions can be executed for causing the machine to perform any one or more of the methodologies discussed herein. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative embodiments, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., ROM, flash memory, DRAM such as SDRAM or Rambus DRAM (RDRAM), etc.), a static memory 606 (e.g., flash memory, static random access memory (SRAM), etc.), and a data storage device 618, which communicate with each other via a bus 630.

The processing device 602 represents one or more general-purpose processing devices such as a microprocessor, a central processing unit, or the like. More particularly, the processing device 602 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 602 can also be one or more special-purpose processing devices such as an application-specific integrated circuit (ASIC), a field programmable gate array (FPGA), a digital signal processor (DSP), a network processor, or the like. The processing device 602 is configured to execute instructions 626 for performing the operations and steps discussed herein. The computer system 600 can further include a network interface device 608 to communicate over a network 620.

The data storage device 618 can include a machine-readable storage medium 624 (also known as a computer-readable medium) on which is stored one or more sets of instructions 626 or software embodying any one or more of the methodologies or functions described herein. For some embodiments, the machine-readable storage medium 624 is a non-transitory machine-readable storage medium. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage device 618, and/or main memory 604 can correspond to the memory sub-system 110 of FIG. 1.

In one embodiment, the instructions 626 include instructions to implement functionality corresponding to compression on a memory system controller of data generated by multiple reads performed on a set of pages of a memory device as described herein (e.g., the on-controller read data compressor/decompressor 113 of FIG. 1). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

In view of the above-described implementations of subject matter this application discloses the following list of examples, wherein one feature of an example in isolation or more than one feature of an example, taken in combination and, optionally, in combination with one or more features of one or more further examples are further examples also falling within the disclosure of this application.

Example 1 is a system comprising: a memory device; and a system controller that comprises a processing device and a controller memory, the processing device being operatively coupled to the memory device and being configured to perform operations comprising: receiving, from a management operation, a request to perform a plurality of page reads on a set of pages of the memory device at a plurality of different read voltage levels within a read window; and in response to the request, causing the plurality of page reads to be performed on the set of pages at the plurality of different read voltage levels within the read window, the plurality of page reads generating voltage information data in a set of page buffers of the memory device; receiving, from the set of page buffers, the voltage information data for the set of pages, the voltage information data describing voltage charges of memory cells of the set of pages; compressing the voltage information data to generate compressed voltage information data; and storing the compressed voltage information data in the controller memory.

In Example 2, the subject matter of Example 1 comprises, wherein the compressing occurs as the voltage information data is received from the set of page buffers by the memory controller.

In Example 3, the subject matter of Examples 1-2 comprises, wherein the request is a first request, and wherein the operations comprise: receiving, from the management operation, a second request to read the voltage information data from the controller memory; and in response to the second request: reading the compressed voltage information data from the controller memory; generating a copy of the voltage information data by decompressing the compressed voltage information data; and providing the copy of the voltage information data to the management operation.

In Example 4, the subject matter of Example 3 comprises, wherein the decompressing occurs as the compressed voltage information data is read from the controller memory.

In Example 5, the subject matter of Examples 3-4 comprises, wherein the compressed voltage information data is stored in a first portion of the controller memory, and wherein the compressed voltage information data is decompressed to a second portion of the controller memory.

In Example 6, the subject matter of Examples 3-5 comprises, wherein the operations comprise: removing the compressed voltage information data from the controller memory after the generating of the copy of the voltage information data.

In Example 7, the subject matter of Examples 1-6 comprises, wherein the read window is centered around a hard voltage threshold of the set of pages.

In Example 8, the subject matter of Examples 1-7 comprises, wherein the management operation is one of a read level calibration operation.

In Example 9, the subject matter of Examples 1-8 comprises, wherein read voltage levels of the plurality of different read voltage levels are based on a predetermined voltage difference.

In Example 10, the subject matter of Example 9 comprises, wherein the predetermined voltage difference is 40 mV.

In Example 11, the subject matter of Examples 1-10 comprises, wherein the read window has a size of 160 mV.

In Example 12, the subject matter of Examples 1-11 comprises, wherein the voltage information data comprises soft information data for the set of pages.

In Example 13, the subject matter of Examples 1-12 comprises, wherein the voltage information data comprises hard information data for the set of pages.

In Example 14, the subject matter of Examples 1-13 comprises, wherein the voltage information data comprises one-hard-one-soft (1H1S) information data for the set of pages.

In Example 15, the subject matter of Examples 1-14 comprises, wherein the voltage information data comprises one-hard-two-soft (1H2S) information data for the set of pages.

In Example 16, the subject matter of Examples 1-15 comprises, wherein the memory device comprises a NOT-AND (NAND)-type memory device, and wherein the set of page buffers comprises a set of latches.

Example 17 is at least one machine-readable medium comprising instructions that, when executed by a processing device of a memory sub-system, cause the processing device to perform operations to implement of any of Examples 1-16.

Example 18 is a method to implement of any of Examples 1-16.

Example 19 is a method comprising: causing, by a processing device of a memory sub-system controller, a plurality of page reads to be performed on a set of pages of a memory device at a plurality of different read voltage levels within a read window, the plurality of page reads generating voltage information data in a set of page buffers of the memory device; receiving from the set of page buffers, by the processing device, the voltage information data for the set of pages, the voltage information data describing voltage charges of memory cells of the set of pages; compressing, by the processing device, the voltage information data to generate compressed voltage information data; storing, by the processing device, the compressed voltage information data in a controller memory of the memory sub-system controller.

In Example 20, the subject matter of Example 19 comprises, reading, by the processing device, the compressed voltage information data from the controller memory; generating, by the processing device, a copy of the voltage information data by decompressing the compressed voltage information data; and using, by the processing device, the copy of the voltage information data to perform a decode operation on at least a portion of a select page of the set of pages.

Example 21 is a system to implement any of Examples 19-20.

Example 22 is at least one machine-readable medium comprising instructions that, when executed by a processing device of a memory sub-system, cause the processing device to perform operations to implement of any of Examples 19-20.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (e.g., non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a ROM, RAM, magnetic disk storage media, optical storage media, flash memory components, and so forth.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device; and
a system controller that comprises a processing device and a controller memory, the processing device being operatively coupled to the memory device and being configured to perform operations comprising:
receiving, from a management operation, a request to perform a plurality of page reads on a set of pages of the memory device at a plurality of different read voltage levels within a read window;
in response to the request, causing the plurality of page reads to be performed on the set of pages at the plurality of different read voltage levels within the read window, the plurality of page reads generating voltage information data in a set of page buffers of the memory device;
receiving, from the set of page buffers, the voltage information data for the set of pages, the voltage information data describing voltage charges of memory cells of the set of pages;
compressing the voltage information data to generate compressed voltage information data; and
storing the compressed voltage information data in the controller memory.

2. The system of claim 1, wherein the compressing occurs as the voltage information data is received from the set of page buffers by the memory controller.

3. The system of claim 1, wherein the request is a first request, and wherein the operations comprise:
receiving, from the management operation, a second request to read the voltage information data from the controller memory; and
in response to the second request:
reading the compressed voltage information data from the controller memory;
generating a copy of the voltage information data by decompressing the compressed voltage information data; and
providing the copy of the voltage information data to the management operation.

4. The system of claim 3, wherein the decompressing occurs as the compressed voltage information data is read from the controller memory.

5. The system of claim 3, wherein the compressed voltage information data is stored in a first portion of the controller memory, and wherein the compressed voltage information data is decompressed to a second portion of the controller memory.

6. The system of claim 3, wherein the operations comprise:
removing the compressed voltage information data from the controller memory after the generating of the copy of the voltage information data.

7. The system of claim 1, wherein the read window is centered around a hard voltage threshold of the set of pages.

8. The system of claim 1, wherein the management operation is one of a read level calibration operation.

9. The system of claim 1, wherein read voltage levels of the plurality of different read voltage levels are based on a predetermined voltage difference.

10. The system of claim 9, wherein the predetermined voltage difference is 40 mV.

11. The system of claim 1, wherein the read window has a size of 160 mV.

12. The system of claim 1, wherein the voltage information data comprises soft information data for the set of pages.

13. The system of claim 1, wherein the voltage information data comprises hard information data for the set of pages.

14. The system of claim 1, wherein the voltage information data comprises one-hard-one-soft (1H1S) information data for the set of pages.

15. The system of claim 1, wherein the voltage information data comprises one-hard-two-soft (1H2S) information data for the set of pages.

16. The system of claim 1, wherein the memory device comprises a NOT-AND (NAND)-type memory device, and wherein the set of page buffers comprises a set of latches.

17. At least one non-transitory machine-readable storage medium comprising instructions that, when executed by a processing device of a memory sub-system controller of a memory sub-system, cause the processing device to perform operations comprising:
receiving, from a management operation, a request to perform a plurality of page reads on a set of pages of a memory device of the memory sub-system at a plurality of different read voltage levels within a read window;
in response to the request, causing the plurality of page reads to be performed on the set of pages at the plurality of different read voltage levels within the read window, the plurality of page reads generating voltage information data in a set of page buffers of the memory device;
receiving, from the set of page buffers, the voltage information data for the set of pages, the voltage information data describing voltage charges of memory cells of the set of pages;
compressing the voltage information data to generate compressed voltage information data; and
storing the compressed voltage information data in a controller memory of the memory sub-system controller.

18. The at least one non-transitory machine-readable storage medium of claim 17, wherein the request is a first request, and wherein the operations comprise:
receiving, from the management operation, a second request to read the voltage information data from the controller memory; and
in response to the second request:
reading the compressed voltage information data from the controller memory;
generating a copy of the voltage information data by decompressing the compressed voltage information data; and
providing the copy of the voltage information data to the management operation.

19. A method comprising:
causing, by a processing device of a memory sub-system controller, a plurality of page reads to be performed on a set of pages of a memory device at a plurality of different read voltage levels within a read window, the plurality of page reads generating voltage information data in a set of page buffers of the memory device;
receiving from the set of page buffers, by the processing device, the voltage information data for the set of pages, the voltage information data describing voltage charges of memory cells of the set of pages;
compressing, by the processing device, the voltage information data to generate compressed voltage information data; and
storing, by the processing device, the compressed voltage information data in a controller memory of the memory sub-system controller.

20. The method of claim 19, comprising:
reading, by the processing device, the compressed voltage information data from the controller memory;
generating, by the processing device, a copy of the voltage information data by decompressing the compressed voltage information data; and
using, by the processing device, the copy of the voltage information data to perform a decode operation on at least a portion of a select page of the set of pages.
